(19) United States
(12) Patent Application Publication
(10) Pub. No.: US 2026/0140012 A1
(43) Pub. Date: May 21, 2026

(54) METHOD AND DEVICE FOR DETERMINING WAVEFRONT ABERRATIONS CAUSED BY AN OPTICAL SYSTEM

(71) Applicant: Carl Zeiss SMT GmbH, Oberkochen (DE)

(72) Inventors: Robert Nicholls, Augsburg (DE); Bruno Langbehn, Berlin (DE)

(21) Appl. No.: 19/391,196

(22) Filed: Nov. 17, 2025

(30) Foreign Application Priority Data
Nov. 19, 2024 (DE) 102024133809.1

(51) Int. Cl. G01M 11/02; G03F 7/00

(52) U.S. Cl. CPC G01M 11/0257; G03F 7/706

(57) ABSTRACT

The invention relates to a method and a device for determining wavefront aberrations caused by an optical system. Within the scope of a method according to the invention, in the optical system, an object field that is illuminated by way of an illumination system and situated in an object plane is imaged into an image field that is situated in an image plane by use of a projection lens, wherein, for at least one field point in the image plane, a plurality of measurements of the respective wavefront aberration generated at this field point are taken, with these measurements differing from one another in terms of the respective effective exit pupil of the beam path.

### CROSS-REFERENCE TO RELATED APPLICATION

This application claims priority of German Patent Application DE 10 2024 133 809.1, filed on Nov. 19, 2024. The content of this application is hereby incorporated by reference in its entirety.

### TECHNICAL FIELD

The invention relates to a method and a device for determining wavefront aberrations caused by an optical system, with the possibility of calculating corrections.

### BACKGROUND

Microlithography is used to produce microstructured component parts, such as integrated circuits or LCDs. The microlithography process is performed in what is known as a projection exposure apparatus, which comprises an illumination device and a projection lens. The mask (=reticle) illuminated by use of the illumination device is in this case projected by use of the projection lens onto a substrate (e.g., a silicon wafer) that is coated with a light-sensitive layer (photoresist) and arranged in the image plane of the projection lens, in order to transfer the mask structure to the light-sensitive coating on the substrate.

In the lithography process, there is a need to test the mask quickly and easily, if possible, under conditions similar to those that are actually present in the projection exposure apparatus. For this purpose, the use of mask inspection systems is known, which for their part have an illumination system and a projection lens, wherein the illuminated region of the mask is imaged onto a sensor arrangement such as, e.g., a charge coupled device (CCD) camera by use of the projection lens.

In the course of the development of lithography systems having an ever higher resolution capability and the attendant increasing accuracy requirements, performing the respective adjustment method in the course of which the respective optical system “is brought to specification” using available degrees of freedom (e.g., setting of manipulators, mirror shape, mechanical changes, etc.) also poses an increasingly demanding challenge. In particular, occurrent wavefront aberrations can be reduced or minimized during this adjustment by manipulating the position of one or more optical elements in the respective optical system (in particular in the projection exposure apparatus or in the mask inspection system).

In this case, it is desirable as a matter of principle to subject the component(s) responsible for the occurrent wavefront aberration to the respective (position) manipulation. This gives rise to the need not only to quantitatively ascertain the wavefront aberrations generated during imaging in the respective optical system but rather associate these in a targeted manner with the respective causative optical elements within the optical system. In particular, a known approach in this respect is that of utilizing the field dependence of said wavefront aberrations, inasmuch as, for instance, aberrations with comparatively low field dependence (for which virtually the same aberration is thus generated at all field points) are associated with optical elements that are comparatively close to the pupil within the system, whereas aberrations with comparatively high field dependence are rather associated with optical elements close to the field.

However, a problem occurring here in practice is that optical systems with comparatively small object field sizes (in particular mask inspection systems and microscopes) only have correspondingly small field profiles of the respective aberration, with the result that said association between an ascertained wavefront aberration and the respective causative (in particular near-pupil or near-field) optical element can only still be established with difficulties or not at all. As a result, this also leads to an ultimately inadequate adjustment and hence a lower optical performance of the optical system in question.

Regarding the prior art, reference is made merely by way of example to WO 2010/034674 A1, DE 10 2012 205 096 B3, DE 10 2015 206 448 B4 and DE 10 2018 219 127 A1.

### SUMMARY

Against the aforementioned background, a problem addressed by the present invention is that of providing a method and a device for determining wavefront aberrations caused by an optical system, by use of which or using which it is possible to associate, in a targeted manner, occurrent wavefront aberrations with the respective causative optical elements and hence also possible to bring about a correspondingly targeted adjustment even in the case of a comparatively small object field size while the above-described issues are at least partially avoided.

This problem is solved by the method as per the features of independent claim 1 and by the apparatus as per alternative independent claim 13.

According to one aspect, the invention relates to a method for determining wavefront aberrations caused by an optical system,
wherein, in the optical system, an object field that is illuminated by way of an illumination system and situated in an object plane is imaged into an image field that is situated in an image plane by use of a projection lens; and
wherein, for at least one field point in the image plane, a plurality of measurements of the respective wavefront aberration generated at this field point are taken, with these measurements differing from one another in terms of the respective effective exit pupil of the beam path.

In particular, the invention is based on the concept of realizing a separation of the respective aberration contributions from different optical elements within the scope of determining wavefront aberrations caused by an optical system such as, e.g., a projection lens of a mask inspection system, by virtue of determining the wavefront aberration generated in the optical system for one or more field points multiple times—to be precise while varying the respective effective exit pupil.

Here and below, “effective exit pupil” is understood to mean the respective angle distribution with which the respective light is incident on the image plane or a field point located therein during imaging, in accordance with the usual terminology.

Depending on the specific application scenario, the aforementioned optical elements might be, e.g., lens elements or mirrors.

As yet to be described in detail below, the variation according to the invention of the effective exit pupil can be effected by way of trimming the optical beam path using one or more aperture stops, in particular also by using a manipulable aperture stop or by changing the shape and/or the size (in relation to the utilized angular space) of the effective exit pupil.

In this case, the optical beam path may be trimmed in particular in relation to the optical beam path upstream of a last image-plane-side optical element in the optical system. In particular, the optical beam path may also be trimmed in relation to the optical beam path upstream of a first object-plane-side optical element in the optical system.

Moreover, the optical beam path may alternatively be trimmed directly in the exit pupil (in relation to the optical beam path downstream of a pupil plane in the optical system) or on the side of the entrance pupil (corresponding to the angular distribution of the light emanating from a field point in the object plane, and in relation to the optical beam path upstream of a pupil plane in the optical system).

Proceeding from the aforementioned principle of varying the effective exit pupil, the invention now makes use of the circumstance that the extent to which, in the event of said variation, a change in the respective measured wavefront aberration is determined allows inferences to be drawn as to whether the optical element responsible for the wavefront aberration is a near-pupil or near-field optical element. In this context, wavefront aberrations that are virtually constant when varying the exit pupil plane can be traced back to near-field optical elements, whereas comparatively strongly varying aberrations (that change relatively strongly when the exit pupil is varied) can be traced back to near-pupil optical elements.

As a result, a targeted association between occurrent wavefront aberrations and the respective causative optical elements and hence also a correspondingly targeted adjustment are rendered possible even in optical systems having a comparatively small object field size.

The invention thus includes the principle of deliberately introducing asymmetry into the optical system by way of trimming the optical beam path during the imaging, in order thus to enable the desired association between a present wavefront aberration and the causative optical element—and hence also enable a targeted adjustment. In this context, the maximally optically realizable exit pupil is restricted to only a portion in each case (i.e., to a “partial pupil”) in particular during the respective measurements, wherein the relevant partial pupil may in turn be modified, in particular displaced, for different measurements. In other words, only a reduced region of the maximally available exit pupil is used for the imaging in each of the aforementioned measurements, and this reduced region can in turn be placed in particular at mutually different positions in the optical system, in order to pass illumination through the optical system with mutually separate portions of said maximally possible exit pupil.

According to an embodiment, the measurements differ from one another in terms of the shape and/or the size of the exit pupil.

According to an embodiment, the optical beam path is trimmed in each case for different measurements by using at least one aperture stop.

According to an embodiment, the optical beam path is trimmed in relation to the optical beam path upstream of a last image-plane-side optical element in the optical system. Such a configuration is advantageous in that the thermal load on said last image-plane-side optical element is reduced.

According to an embodiment, the optical beam path is trimmed in relation to the optical beam path upstream of a first object-plane-side optical element in the optical system. Such a configuration is advantageous in that this achieves a maximal reduction in the thermal load on the optical elements present in the optical system.

According to an embodiment, the optical beam path is trimmed in relation to the optical beam path upstream of a pupil plane in the optical system.

According to a further embodiment, the optical beam path is trimmed in relation to the optical beam path downstream of a pupil plane in the optical system.

According to an embodiment, the effective exit pupil is changed in each case for different measurements by using at least one manipulable aperture stop.

According to an embodiment, depending on a variation of the respective wavefront aberration generated during the different measurements, the wavefront aberration is associated with a causative optical element in the projection lens.

According to an embodiment, the causative optical element is subjected to a manipulation, in particular a position manipulation, on the basis of this association and the measurements of the wavefront aberration.

According to an embodiment, this manipulation is effected in such a way that a wavefront aberration generated in the image plane in the optical system is reduced in comparison with a configuration without the manipulation.

According to an embodiment, the method according to the invention is performed on a projection lens of a mask inspection system.

The invention also relates to a device that is designed to carry out a method having the features described above. With regard to advantages and advantageous configurations of the sensor arrangement or of the device, reference is made to the embodiments above in relation to the method according to the invention.

Further embodiments of the invention can be gathered from the description and the dependent claims.

The invention is explained in more detail below on the basis of an exemplary embodiment and with reference to the attached figures.

### BRIEF DESCRIPTION OF DRAWINGS

In the drawings:

FIG. 1 shows a schematic illustration for explaining the principle underlying the method according to the invention using an exemplary embodiment;

FIGS. 2A-2B show schematic illustrations for explaining a problem underlying the present invention on the basis of a comparison of possible scenarios during a conventional determination of wavefront aberrations in a projection lens with a comparatively large object field (FIG. 2A) and in a mask inspection system with a comparatively small object field (FIG. 2B); and

FIG. 3 shows a schematic illustration of the fundamentally possible construction of a mask inspection system as an exemplary application of the present invention.

### DETAILED DESCRIPTION

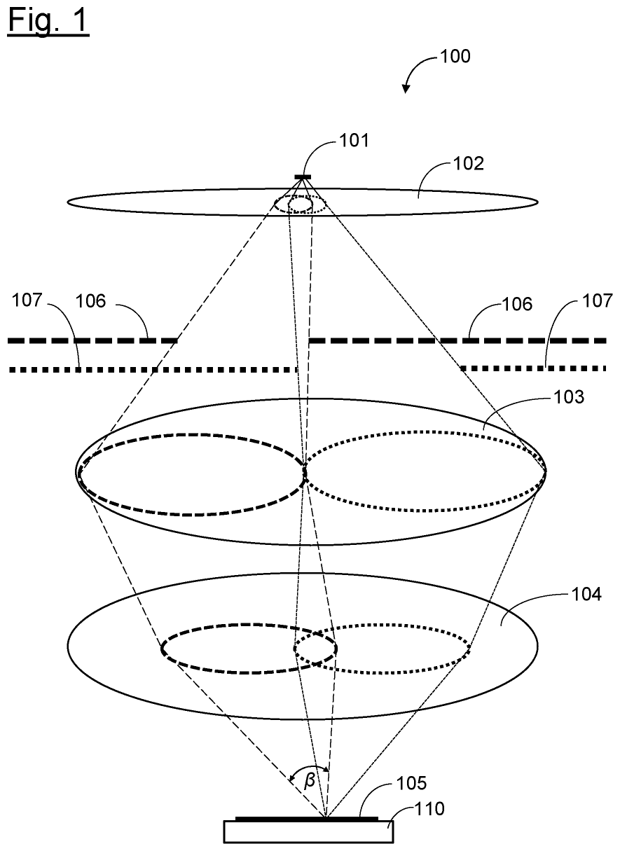

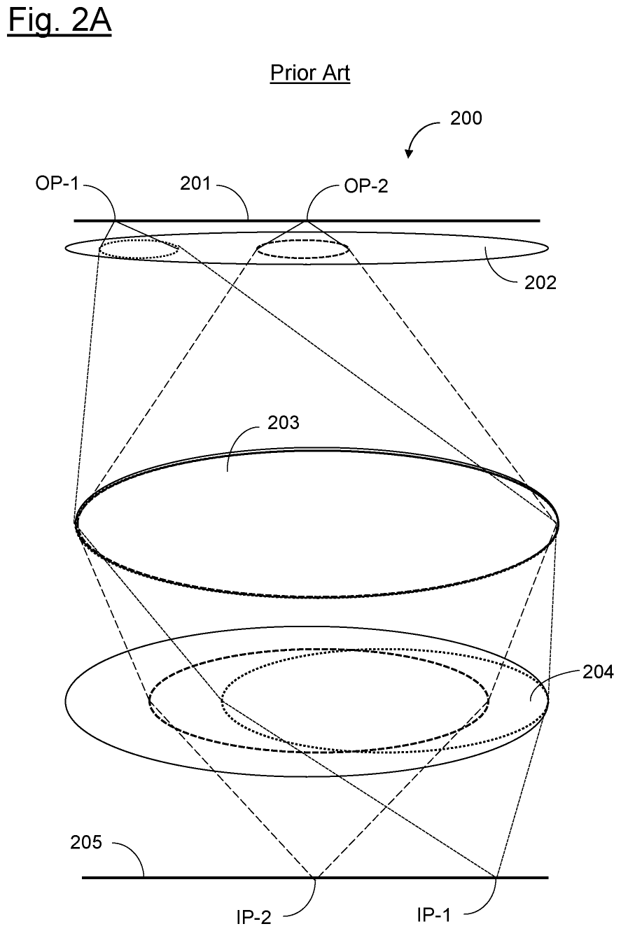

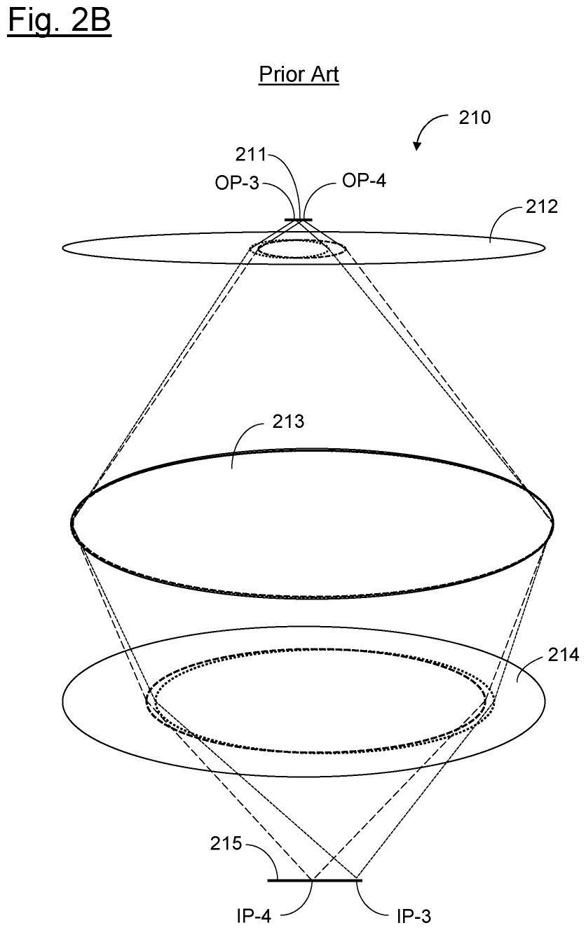

The principle underlying the present method is explained below on the basis of an exemplary embodiment, with reference being made to the schematic illustration in FIG. 1. However, this is preceded by a brief explanation of the underlying problem of the invention, which has already been mentioned in the introduction, with reference being made to FIGS. 2A-2B.

FIGS. 2A and 2B each illustrate a conventional scenario in the determination of wavefront aberrations or in the association thereof with causative optical elements in the respective system, with FIG. 2A depicting, in a much simplified illustration, a projection lens 200 with a comparatively large object field 201 (e.g., a projection lens in a microlithographic projection exposure apparatus) and FIG. 2B depicting a projection lens 210 of a mask inspection system with a comparatively small object field 211. Examples of wavefront aberrations are astigmatism, coma, and spherical aberration.

The projection lens 200 includes optical elements 202, 203, and 204, and the projection lens 210 includes optical elements 212, 213, and 214. The respective optical elements of the optical system that bring about the imaging of the object field 201 or 211 into the image field 205 or 215 are denoted by “202, 203 and 204” in FIG. 2A and by “212, 213 and 214” in FIG. 2B. In this case, the optical elements 202 and 212 both are near-field elements, and the optical elements 203 and 213 both are near-pupil optical elements. In FIG. 2A and FIG. 2B, optical elements 202, 203, 204, 212, 213, 214 are lenses. In other embodiments, optical elements of the projection lens 200 or 210, respectively, can also be embodied as mirrors.

Whereas there is a comparatively good separation in respect of their aberration contribution between near-field and near-pupil optical elements, i.e., a comparatively good association between the aberration and the respective causative optical element, on the basis of a conventional implementation of the aberration measurement for different field points in the scenario of FIG. 2A (where two exemplary field points in the object plane are denoted as OP-1 and OP-2 and where two exemplary field points in the image plane are denoted as IP-1 and IP-2, this procedure fails in the scenario of FIG. 2B (where two exemplary field points in the object plane are denoted as OP-3 and OP-4 and where two exemplary field points in the image plane are denoted as IP-3 and IP-4. This is because, according to FIG. 2B, largely coinciding aberrations are measured for different field points in the image field as a result of the relatively small object field, and so it is not possible to establish a targeted association between a respective specifically measured wavefront aberration and the causative optical element (in the sense of a decision whether this is a near-field or near-pupil element).

In order to overcome this problem, the respective occurrent wavefront aberration is now measured repeatedly in accordance with FIG. 1 for one or more field points in the image field denoted by “105”, with these measurements differing from one another in terms of the respective exit pupil. A sensor 110 is placed at the image field 105. In order to determine aberration, images on a certain measurement structure are taken with different acquisition parameters (e.g., different focus positions) and evaluated for measurement values.

Specifically, to this end and in accordance with FIG. 1, the optical beam path on the side of the entrance pupil is trimmed in different ways in a projection lens 100 for said measurements, and this is in turn achieved by the use of aperture stops 106 and 107. In the illustrated example, the projection lens 100 includes optical elements 102, 103 and 104. Further, in the shown embodiment, the optical elements 102, 103 and 104 are lenses, but in other embodiments they can also be mirrors.

In the context of the present application, “trimming the optical beam path” means to reduce the pupil by adjusting the pupil aperture (i.e., changing a mechanical aperture stop or partially closing an adjustable iris aperture). The aperture stops may, e.g., be made of stainless-steel sheet metal. Aperture stops 106 and 107 may have round apertures of different sizes and/or different shapes and/or different geometric arrangement, e.g., horizontally arranged apertures (“X-dipol”) or vertically arranged apertures (“Y-dipol”). Aperture stops 106 and 107 may also have adjustable (iris-) apertures.

In this context, the optical beam path generated by using the aperture stop 106 (but without the aperture stop 107) is plotted using a long dashed line, and the optical beam path generated by using the aperture stop 107 (but without the aperture stop 106) is plotted using a short dashed line. It is evident from FIG. 1 that the two beam paths differ significantly in respect of the respective exit pupil and also in respect of the sub-aperture generated in the pupil plane or on a near-pupil optical element 103. “Exit pupil” means the angular distribution of the light incident on the relevant field point in the image field 105 (wherein in FIG. 1, just for illustration purposes, such an angle is denoted with “β”). Typically, for optics with a high magnification, due to the very small depth of field, a very large portion of the optics can be regarded as close to the pupil plane.

Should a large variation over the different exit pupils set according to the invention now be ascertained for a wavefront aberration specifically measured at a field point in the image field 105, this allows the conclusion to be drawn that the optical element responsible for this aberration is a near-pupil optical element. Conversely, a comparatively small change in the aberration measured at a field point in the image field 105 for different exit pupils allows the conclusion to be drawn that the optical element responsible for this aberration is a near-field element.

Consequently, the influences of different optical elements can be separated on the basis of the measurement data obtained for different exit pupils if the corresponding signatures are available on account of design simulations. Near-pupil optical elements each have a stronger profile of the aberrations when the exit pupil is varied, whereas near-field optical elements exhibit a smaller profile. The adjustment is then implemented by simultaneously taking account of the measured and design aberrations of all exit pupil variations.

In the context of the present application, an optical element is regarded as “near pupil” if this optical element effects all field points simultaneously. An optical element is regarded as “near field” if the optical effect of this optical element is different depending on position of the field point. A plane is regarded as “near field” plane if a structure on the object plane could still be seen in this plane.

According to another possible approach, the terms “close to pupil” and “close to field” may be defined based on the so-called Sub-Aperture-Ratio: A Sub-Aperture-Ratio of 1 corresponds to the pupil planes, a Sub-Aperture-Ratio of infinity corresponds to the field planes. Further, in a possible definition, a Sub-Aperture-Ratio<3 may correspond to “close to pupil” and a Sub-Aperture-Ratio>10 may correspond to “close to field” (everything else being in between).

The variation according to the invention of the exit pupil can be effected using a manipulable aperture stop or else by changing the shape or the size of the exit pupil. The manipulable aperture stop can comprise an aperture stop plate, a holder for holding the aperture stop plate, and an actuator to move the holder. The manipulable aperture stop can in particular comprise one or more adjustable (iris-) apertures. The design must decide for a suitable position of a mechanical stop. Multiple positions are possible. Only the optically free rays contribute to the image.

If the shape or the size of the numerical aperture (NA) is changed, then a corresponding change in a (Zernike) expansion system of the measured wavefront should optionally also be taken into account during the adjustment yet to be described below.

For the adjustment calculation itself, it is possible both to optimize all pupil positions for individual field points (as described in the following example) and to simultaneously optimize multiple field points and pupil positions. Here, “all pupil positions” means all variations of the pupil which could for example be established by changing the position of a pupil aperture, by adjusting the aperture size of an iris aperture, or, by changing a swappable mechanical aperture sheet and thereby changing the pupil form.

Mathematically, the following problem is solved or at least approximated when minimizing the aberrations:

$${min}_{x ∈ X} ( b - Mx ) \qquad ( 1 )$$

In this case, b denotes the vector of all measured aberrations, x denotes the vector of all degrees of freedom to be adjusted, X denotes the set of all permissible travels (e.g., limited by maximum travel ranges of manipulators) and M denotes a matrix that describes how the individual degrees of freedom act on the aberrations (wherein the corresponding entries in the matrix M are also referred to as “sensitivities”). In the conventional adjustment concept, the vector b has the following entries:

$$( \begin{matrix}{b}_{1 , 1} \\ {b}_{1 , 2} \\ ⋯ \\ {b}_{1 , n} \\ {b}_{2 , 1} \\ {b}_{2 , 2} \\ ⋯ \\ {b}_{2 , n} \\ ⋯ \\ {b}_{l , 1} \\ {b}_{l , 2} \\ ⋯ \\ {b}_{l , n}\end{matrix} ) \begin{matrix}\} & \begin{matrix} \\ \\ Aberrations of field point 1 \\ \end{matrix} \\ \} & \begin{matrix} \\ \\ Aberrations of field point 2 \\ \end{matrix} \\ \} & \begin{matrix} \\ \\ Aberrations of field point 1 \\ \end{matrix}\end{matrix}$$

In this case, the aberrations for each field point (indexed from 1 to l) are represented in a base system with n coefficients (e.g., Zernike coefficients). The vector b thus has a length of l·n. The vector x is in the form of

$$( \begin{matrix}{x}_{1} \\ {x}_{2} \\ ⋮ \\ {x}_{k}\end{matrix} ) ,$$

where the lens has k degrees of freedom for the adjustment.

Accordingly, the matrix M∈ [symbol] has the following form:

$$( \begin{matrix}{m}_{1 , 1 , 1} & ⋯ & {m}_{1 , 1 , k} \\ ⋮ & ⋱ & ⋮ \\ {m}_{l , n , 1} & ⋯ & {m}_{l , n , k}\end{matrix} ) \qquad ( 2 )$$

where mᵢ_{₁}_{,i}_{₂}_{,i}_{₃} describes the change in the aberration coefficient i₂ at the field point i₁ when adjusting the degree of freedom i₃ by one unit. For example, algorithms known per se are used to solve this problem, wherein, regarding the prior art, reference is made purely by way of example to DE 10 2012 205 096 B3, the further references cited therein, and U.S. Pat. No. 10,303,063, the entire content of which is incorporated by reference. In a production set up b is typically the measured values (but could also be simulated values in a design phase). M is fixed per the measurement and adjustment setup und represents the design behaviour of the system. M can be reduced or appended if non-adjustable degrees of freedom or additional field points or pupil variations are to be investigated. x can be adjusted in order to achieve the predicted performance.

A measurement is done which uses a fixed set of pupil variations. During the measurement a computer is used to control the system via a software which can execute the necessary measurement steps (e.g., moving or changing the pupil aperture using mechanical motors/actuators/handling robots or by prompt and manual interaction, switching on the light, acquiring an image by controlling the camera/sensor). Typically for each pupil variation a set of images is required (e.g., at different focus positions or on different measurement structures on the mask (in the object plane)). These sets of images are evaluated on the same or on a separate computer to extract the measurement values from the image data. The provided data is now represented in the vector b. After minimizing the expected aberrations (b−Mx) with restrictions on x, using an appropriate algorithm (for example, quadratic programming) the system is improved by adjusting the degrees of freedom in x. After the adjustment a new measurement is started to verify the success.

In order to calculate an adjustment concept in the method according to the invention, the same mathematical problem may be solved

$${min}_{x ∈ X} ( b - Mx ) \qquad ( 1 )$$

wherein the variables have to be adapted accordingly. Thus, the vector b is now represented by the following entries:

$$\begin{matrix}( \begin{matrix}{b}_{1 , 1 , 1} \\ ⋯ \\ {b}_{1 , l , n} \\ {b}_{2 , 1 , 1} \\ ⋯ \\ {b}_{2 , l , n} \\ ⋯ \\ {b}_{p , 1 , 1} \\ ⋯ \\ {b}_{p , l , n}\end{matrix} ) & \begin{matrix}\} \begin{matrix} \\ Pupil variation 1 \\ \end{matrix} \\ \} \begin{matrix} \\ Pupil variation 2 \\ \end{matrix} \\ \} \begin{matrix} \\ Pupil variation p \\ \end{matrix}\end{matrix}\end{matrix}$$

The vector b thus now has a length of l·n·p. The vector x remains identical to the conventional adjustment concept, but the matrix M must likewise be augmented by the effects for the different pupil variations 1 to p to read

$$M = ( \begin{matrix}{m}_{1 , 1 , 1 , 1} & ⋯ & {m}_{1 , 1 , 1 , k} \\ ⋮ & ⋱ & ⋮ \\ {m}_{p , l , n , 1} & ⋯ & {m}_{p , l , n , k}\end{matrix} )$$

where mᵢ_{₁}_{,i}_{₂}_{,i}_{₃}_{,i}_{₄} now describes the change in the aberration coefficient i₃ at the field point i₂ for the pupil setting i₁ when adjusting the degree of freedom i₄ by one unit.

Optimization algorithms known per se can be used to solve the minimization problem, wherein, again merely by way of example, reference is made to DE 10 2012 205 096 B3 and the further references cited therein. The optimization algorithms may comprise a quadratic programming as already described above. In the method according to the invention, the size of the vector b and of the matrix M is multiplied by the number of pupil variations introduced. Since the number l is very small in the application scenario of a mask inspection system on account of the comparatively small number of measurable field points, the enlargement of the matrix M in this case generally does not lead to a significant increase in the computing time or the scope of the algorithm to be used in each case.

The causative optical element is the largest entry in the vector x (depending on units used and expectation of accuracy of this degree of freedom). The causative optical element(s) are manipulated, e.g., by moving the actuators in the corresponding degree of freedom by the value x_i or by disassembling and reassembling at a new position (different by x_i). The expectation from the model M is that the aberrations are reduced to the expected value b−Mx. This is verified after manipulation by repeating the same measurement on the improved system.

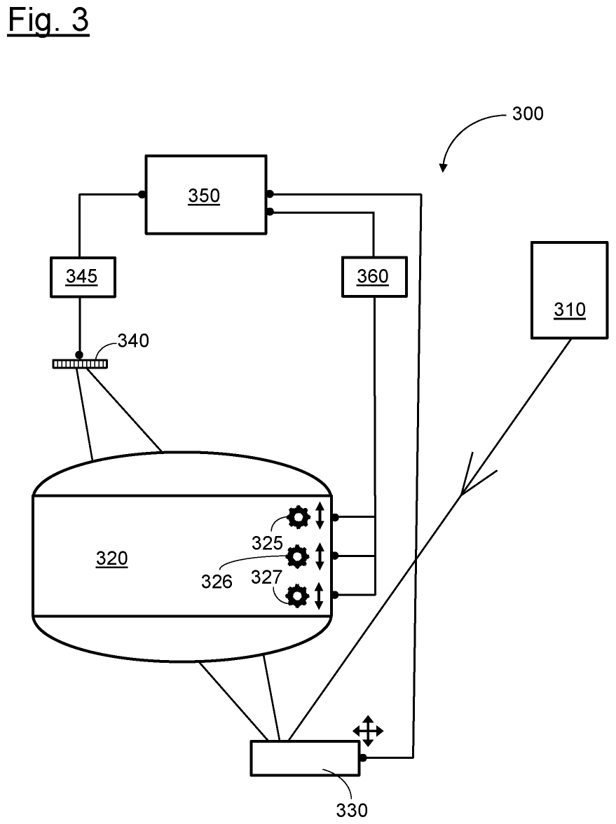

FIG. 3 shows a schematic illustration of the fundamentally possible construction of a mask inspection system 300 as an exemplary application of the present invention. The mask inspection system 300 does not show single optical elements but rather summarizes an optical projection system, i.e., a system like FIG. 2B, possibly containing near-field and near-pupil optical elements.

As illustrated purely schematically in FIG. 3, a mask inspection system 300 comprises an illumination system 310 and a projection lens 320, wherein light from a light source (not depicted in FIG. 3) enters into the illumination system 310 and is incident on a mask 330 arranged in the object plane of the projection lens 320, and wherein the illuminated region of the mask 330 is imaged onto a sensor arrangement 340 by way of the projection lens. For example, the sensor arrangement 340 can include a charge coupled device sensor or a complementary metal oxide semiconductor (CMOS) sensor. The sensor can have one or more arrays of individually addressable sensing elements (or pixels). In order to make a prediction of the imaging result obtained with a mask when the lithography process is performed in a projection exposure apparatus, an intensity distribution that is obtained for the mask in the mask inspection system of FIG. 3 or with the sensor arrangement is initially measured. In this case, the same wavelength that is also used during the lithography process in the projection exposure apparatus is preferably used in the mask inspection system.

Also schematically shown in FIG. 3 is a computer 350 for processing the image signals 345 from the sensor 340 and for performing the computations. A controller 360 and actuators 325, 326, 327 are used for controlling the shape and/or size of the exit pupil and for manipulating the causative optical element(s) to reduce waveform aberration.

In some examples, the mask inspection system 300 can include a computer that causes the system to perform the processes described above, e.g., based at least in part on an execution of a computer program stored in a storage device of the computer. For example, the computer can include one or more data processors, such as central processing units (CPUs) and/or graphics processing units (GPUs). Each data processor can include one or more processor cores, one or more memory devices, and or more controllers, and one or more communication devices. For example, the computer can be communicatively coupled to the components of the system 300 such that a signal output by the computer can cause a change in a component of the system 300. For example, the system 300 can include a memory storing the computer program. The computer can execute the computer program. For example, the computer program can be installed on the computer and hence on the system 300 (physically/concretely). In some examples, it is possible that the computer program is stored elsewhere (e.g., in a cloud server) and the system 300 merely has a communication module for receiving instructions that arise from executing the program elsewhere. Thus, the computer program can be executed externally (e.g., on an external computer unit, on a server unit, etc.), and the instructions of the computer program can be transmitted to the communication module of the system 300. For example, the communication module for receiving the instructions can be communicatively coupled to the computer. For example, the communication module can include a reception unit configured to receive and/or process instructions via a wireless and/or wired connection. For example, the synergy of computer program and corresponding apparatus can allow the method to be executed in automated or autonomous fashion within the system 300. Consequently, it is also possible to minimize the intervention, for example by an operator, and so it is possible to minimize both the costs and the complexity when determining wavefront aberrations caused by the optical system 300.

Even though the invention has been described on the basis of specific embodiments, numerous variations and alternative embodiments will be apparent to a person skilled in the art, for example by combining and/or exchanging features of individual embodiments. Accordingly, it goes without saying for a person skilled in the art that such variations and alternative embodiments are also included by the present invention, and the scope of the invention is restricted only within the meaning of the accompanying claims and the equivalents thereof.

What is claimed is:

1. A method for determining wavefront aberrations caused by an optical system,
wherein, in the optical system, an object field that is illuminated by way of an illumination system and situated in an object plane is imaged into an image field that is situated in an image plane by use of a projection lens;
wherein, for at least one field point in the image plane, a plurality of measurements of the respective wavefront aberration generated at this field point are taken, with these measurements differing from one another in terms of the respective effective exit pupil of the beam path.

2. The method of claim 1 wherein the measurements differ from one another in terms of the shape and/or the size of the effective exit pupil.

3. The method of claim 1 wherein the optical beam path is trimmed in each case for different measurements by using at least one aperture stop.

4. The method of claim 3 wherein the optical beam path is trimmed in relation to the optical beam path upstream of a last image-plane-side optical element in the optical system.

5. The method of claim 3 wherein the optical beam path is trimmed in relation to the optical beam path upstream of a first object-plane-side optical element in the optical system.

6. The method of claim 3 wherein the optical beam path is trimmed in relation to the optical beam path upstream of a pupil plane in the optical system.

7. The method of claim 3 wherein the optical beam path is trimmed in relation to the optical beam path downstream of a pupil plane in the optical system.

8. The method of claim 1 wherein the effective exit pupil is changed in each case for different measurements by using at least one manipulable aperture stop.

9. The method of claim 1 wherein depending on a variation of the respective wavefront aberration generated during the different measurements, the wavefront aberration is associated with a causative optical element in the projection lens.

10. The method of claim 9 wherein the causative optical element is subjected to a manipulation, in particular a position manipulation, on the basis of this association and the measurements of the wavefront aberration.

11. The method of claim 10 wherein this manipulation is effected in such a way that a wavefront aberration generated in the image plane in the optical system is reduced in comparison with a configuration without the manipulation.

12. The method of claim 1 wherein said method is performed on a projection lens of a mask inspection system.

13. A device for determining wavefront aberrations caused by an optical system, wherein the device is designed to carry out a method according to claim 1.

14. The device of claim 13 wherein the measurements differ from one another in terms of the shape and/or the size of the effective exit pupil.

15. The device of claim 13 wherein the device is configured to trim the optical beam path in each case for different measurements by using at least one aperture stop.

16. The device of claim 15 wherein the device is configured to trim the optical beam path in relation to the optical beam path upstream of a last image-plane-side optical element in the optical system.

17. The device of claim 15 wherein the device is configured to trim the optical beam path in relation to the optical beam path upstream of a first object-plane-side optical element in the optical system.

18. The device of claim 15 wherein the device is configured to trim the optical beam path in relation to the optical beam path upstream of a pupil plane in the optical system.

19. The device of claim 15 wherein the device is configured to trim the optical beam path in relation to the optical beam path downstream of a pupil plane in the optical system.

20. The device of claim 13 wherein the device is configured to change the effective exit pupil in each case for different measurements by using at least one manipulable aperture stop.
